(19) United States
(12) Patent Application Publication
(10) Pub. No.: US 2018/0057925 A1
(43) Pub. Date: Mar. 1, 2018

(54) DEVICE FOR GROWING MONOCRYSTALLINE CRYSTAL

(71) Applicant: NATIONAL CHUNG SHAN INSTITUTE OF SCIENCE AND TECHNOLOGY, TAOYUAN CITY (TW)

(72) Inventors: DAI-LIANG MA, TAOYUAN CITY (TW); HSUEH-I CHEN, TAOYUAN CITY (TW); BO-CHENG LIN, TAOYUAN CITY (TW); CHENG-JUNG KO, TAOYUAN CITY (TW); YING-CONG ZHAO, TAOYUAN CITY (TW); CHIH-WEI KUO, TAOYUAN CITY (TW); SHU-YU YEH, TAOYUAN CITY (TW)

(21) Appl. No.: 15/353,000

(22) Filed: Nov. 16, 2016

(30) Foreign Application Priority Data
Aug. 26, 2016 (TW) 105127344

(51) Int. Cl. C23C 14/24; C30B 23/02; C30B 23/06; C30B 29/36; C30B 29/40; C23C 14/06; C23C 14/26

(52) U.S. Cl. CPC C23C 14/243; C30B 23/025; C30B 23/066; C23C 14/26; C30B 29/403; C23C 14/0635; C23C 14/0641; C30B 29/36

(57) ABSTRACT

A device for growing large-sized monocrystalline crystals, including a crucible adapted to grow crystals from a material source and with a seed crystal and including therein a seed crystal region, a growth chamber, and a material source region; a thermally insulating material disposed outside the crucible and below a heat dissipation component; and a plurality of heating components disposed outside the thermally insulating material to provide heat sources, wherein the heat dissipation component is of a heat dissipation inner diameter and a heat dissipation height which exceeds a thickness of the thermally insulating material.

### CROSS-REFERENCE TO RELATED APPLICATION

This non-provisional application claims priority under 35 U.S.C. § 119(a) on Patent Application No(s). 105127344 filed in Taiwan, R.O.C. on Aug. 26, 2016, the entire contents of which are hereby incorporated by reference.

### FIELD OF THE INVENTION

The present invention relates to devices for crystal growth and, more particularly, to a device for growing monocrystalline crystals from silicon carbide and nitrides.

### BACKGROUND OF THE INVENTION

Due to rapid development of modern technology and enhancement of quality of life, various 3C high-tech electronic products are becoming thinner, lighter, smaller and more versatile. Therefore, various electronic devices are made from semiconductors, such as silicon carbide (SiC) and group III nitrides (e.g., GaN and AlN). In this regard, silicon carbide and group III nitrides display high physical strength, high resistance to corrosion, and excellent electronic properties, such as high hardness of radiation, high breakdown field strength, wide bandgap, high saturated electron drift velocity, and satisfactory high-temperature operability.

Conventional techniques, such as physical vapor transport (PVT) and physical vapor deposition (PVD), are for use in growing crystals from silicon carbide and group III nitrides include as well as mass production of crystals. PVT involves allowing a silicon carbide powder and a group III nitride powder to undergo sublimation in a muffle furnace and driving gaseous silicon carbide and gaseous group III nitrides to a seed crystal by a temperature gradient so as to undergo a crystal growth process. In general, growing silicon carbide crystals by PVT entails: providing a seed crystal; putting the seed crystal in a crucible which comprises a growth chamber, a seed crystal region (inclusive of a holder disposed above the growth chamber, adapted to fix the seed crystal in place, and positioned at the relative cold end of a heat field device for providing the temperature gradient), and a material source region disposed below the growth chamber and adapted to contain a material source; filling the material source region with a carbide raw material so that the carbide raw material undergoes sublimation to become gas molecules; and conveying the gas molecules to a seed crystal wafer to undergo deposition and crystal growth. Applying PVT to growing crystals from silicon carbide and group III nitrides has disadvantages described below. Take silicon carbide as an example, defects of a graphite thermally-conductive layer extend into a wafer. In 1993, Stein discovered a hexagonal vacancy in a silicon carbide wafer produced by PVT and suggested that it results from planar evaporation of the back of the wafer. The nucleation site of the hexagonal vacancy is located at an imperfect point of the graphite thermally-conductive layer between a seed crystal and a seed pad. During the process of crystal growth, the growth of the bottom (near the seed crystal) of the hexagonal vacancy and the evaporation which occurs at the top (near the growth surface) of the hexagonal vacancy together lead to the movement of the hexagonal vacancy. The hexagonal vacancy originates from the imperfect point of the graphite thermally-conductive layer between the seed crystal and the seed pad. The aforesaid phenomenon also causes 6H (or 15R) polycrystalline insertions, carbon-rich depositions, and pyrolysis-related holes. In view of this, the prior art discloses precluding the defects by plating a uniform photoresist layer on the back of the seed crystal to stop silicon carbide from undergoing local sublimation on the back of the seed crystal which might otherwise occur because of the poor heat transfer caused by the holes, but at the expense of the rate of the growth of the wafer and reproducibility.

Since the quality of a wafer produced by PVT depends on the temperature at which the crystal growth process is carried out, the prior art discloses improving a required apparatus to control the growth process temperature. U.S. Pat. No. 5,968,261 discloses forming a cavity in a graphite crucible and applying a thermally insulating material to the inner wall of the cavity to increase the efficiency of the heat dissipation that takes place on the back of a seed crystal. US20060213430 discloses changing the distance between a seed crystal and a holder thereof to control the efficiency of heat transfer between the seed crystal and the holder as well as heat radiation. U.S. Pat. No. 7,351,286 discloses positioning a seed crystal in a manner to reduce the bending of the seed crystal and the effect of a stress thereon. U.S. Pat. No. 7,323,051 discloses positioning a seed crystal by a porous matter disposed on the back of the seed crystal and providing a vapor blocking layer for reducing the sublimation which occurs to the seed crystal. U.S. Pat. No. 7,524,376 provides a thin-walled crucible and discloses growing an aluminum nitride wafer by PVT to reduce a thermal stress. U.S. Pat. No. 8,147,991 discloses controlling the efficiency of heat transfer by adjusting the distance between a seed crystal and a holder thereof.

The aforesaid prior art involves modifying the shape of a crucible or the shape of a seed crystal holder. However, after a growing wafer has attained a large size, the aforesaid prior art fails to dissipate heat sufficiently from the large-sized wafer, further control the shape of the interface of the growth of the wafer, and speed up the growth rate. In view of this, it is important to provide a device adapted for growing monocrystalline crystals and equipped with a heat dissipation component conducive to high efficiency of heat dissipation of large-sized wafers, good balance between process costs and efficiency, and the growth of large-sized monocrystalline crystals by PVT.

### SUMMARY OF THE INVENTION

In view of the aforesaid drawbacks of the prior art, it is an objective of the present invention to provide a device for growing monocrystalline crystals. The device comprises a crucible, a thermally insulating material, and a plurality of heating components, and features a heat dissipation inner diameter, a heat dissipation outer diameter, and a heat dissipation height, so as to effectively control a heat field. Furthermore, the device features an axial temperature gradient whereby high-quality monocrystalline crystals are grown.

To achieve the above and other objectives, the present invention provides a device for growing monocrystalline crystals, comprising: a crucible adapted to grow crystals from a material source and with a seed crystal and including therein a seed crystal region, a growth chamber, and a material source region; a thermally insulating material disposed outside the crucible and below a heat dissipation component; and a plurality of heating components disposed outside the thermally insulating material to provide heat sources, wherein the heat dissipation component is of a heat dissipation inner diameter and a heat dissipation height which exceeds the thickness of the thermally insulating material.

The crucible is a graphite crucible (but the present invention is not limited thereto.) The seed crystal region disposed at an upper part within the crucible includes a holder for fixing the seed crystal in place. The seed crystal is made of silicon carbide or a nitride (but the present invention is not limited thereto.) The seed crystal is a monocrystalline wafer of a thickness of at least 350 μm and a diameter of 2-6 inches and is for growing monocrystalline crystals which outgrow the seed crystal in size. The monocrystalline wafer is made of silicon carbide or a nitride (but the present invention is not limited thereto.) The material source region disposed at the lower part within the crucible contains a material source. The material source is a silicon carbide powder or a nitride powder (but the present invention is not limited thereto.)

The crucible is enclosed by a thermally insulating material. The thermally insulating material is disposed below a heat dissipation component. The heat dissipation component enhances the heat dissipation taking place in the seed crystal region, controls a heat field in the crucible, increases the axial temperature gradient to thereby increase the wafer growth rate, increases the radial temperature gradient to thereby control the interface shape, thereby enabling the production of high-quality silicon carbide monocrystalline crystals. The thermally insulating material is a graphite felt (but the present invention is not limited thereto.) The graphite felt and the heat dissipation component are either integrally formed or separately formed. The thermally insulating material and heat dissipation component are made of the same material or different materials. The heat dissipation component is made of a porous, thermally insulating carbon material, a graphite, or a graphite felt (but the present invention is not limited thereto.) The heat dissipation component is a hollow-cored cylinder (for example, chimney-shaped), a hollow-cored cuboid, or any other geometric cuboid. Hence, the heat dissipation component has a heat dissipation inner diameter, a heat dissipation outer diameter, and a heat dissipation height. The heat dissipation inner diameter equals 10˜250 mm or 1%˜85% of the outer diameter of an upper portion of the crucible. The heat dissipation outer diameter equals 15˜300 mm or 3%˜100% of the outer diameter of an upper portion of the crucible. The heat dissipation height equals 5˜200 mm (and thus exceeds the thickness of the thermally insulating material.)

The plurality of heating components is disposed outside the thermally insulating material to provide heat sources for heating up the device. Each heating component is a heating coil or a heating resistance wire/netting.

The above summary, the detailed description below, and the accompanying drawings further explain the technical means and measures taken to achieve predetermined objectives of the present invention and the effects thereof. The other objectives and advantages of the present invention are explained below and illustrated with the accompanying drawings.

### BRIEF DESCRIPTION OF THE DRAWINGS

FIG. 1A is a schematic view of a device for growing monocrystalline crystals according to a preferred embodiment of the present invention;

FIG. 1B is a schematic view of the device for growing monocrystalline crystals according to another embodiment of the present invention;

FIG. 2 is a schematic view of a heat dissipation component of the device for growing monocrystalline crystals of the present invention;

FIG. 3 is a schematic view of thermal analysis of the heat dissipation component according to the preferred embodiment of the present invention;

FIG. 4 is a schematic view of thermal analysis of the device for growing monocrystalline crystals according to the preferred embodiment of the present invention;

FIG. 5 is a picture taken of a 6 -inch monocrystalline silicon carbide crystal ball produced by the device for growing monocrystalline crystals according to the preferred embodiment of the present invention;

FIG. 6 is a schematic view of thermal analysis of a heat dissipation component according to the comparative embodiment of the present invention;

FIG. 7 is a schematic view of thermal analysis of the device for growing monocrystalline crystals according to the comparative embodiment of the present invention; and

FIG. 8 is a picture taken of a monocrystalline silicon carbide crystal ball produced by the device for growing monocrystalline crystals according to the comparative embodiment of the present invention.

### DETAILED DESCRIPTION OF THE PREFERRED EMBODIMENTS

The preferred embodiment of the present invention is illustrated with a specific embodiment. Hence, persons skilled in the art can easily gain insight into the advantages and effects of the present invention.

The present invention provides a device for growing monocrystalline crystals. When applied to physical vapor transport (PVT), the device for growing monocrystalline crystals is effective in controlling a heat field, increasing an axial temperature difference, suppressing the growth of a polycrystalline region during the initial stage of the growth of monocrystalline crystals, increasing the range of a monocrystalline region in the course of the growth of a convex interface thereof, bringing about expansive growth of the monocrystalline region, reducing the growth of a polycrystalline crystal and its effect on a monocrystalline crystal, speeding up crystal growth, increasing the yield of crystal growth, and enabling mass production of crystals.

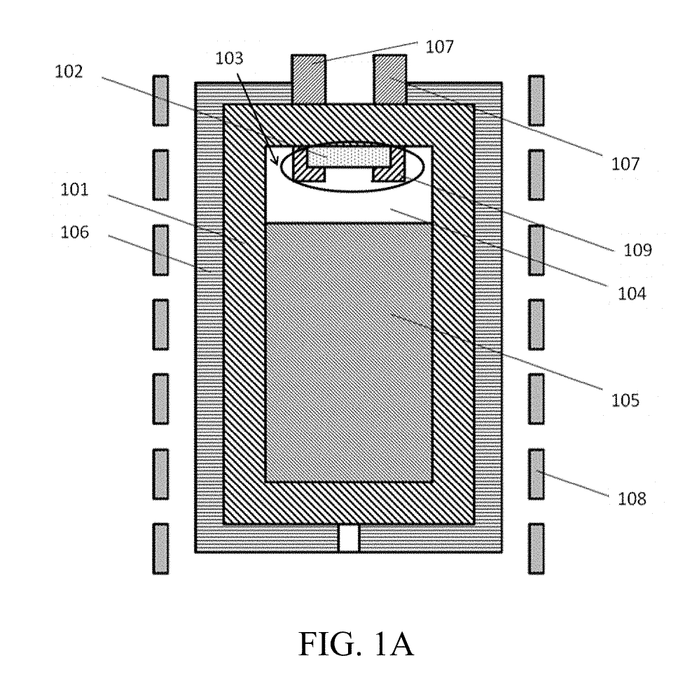

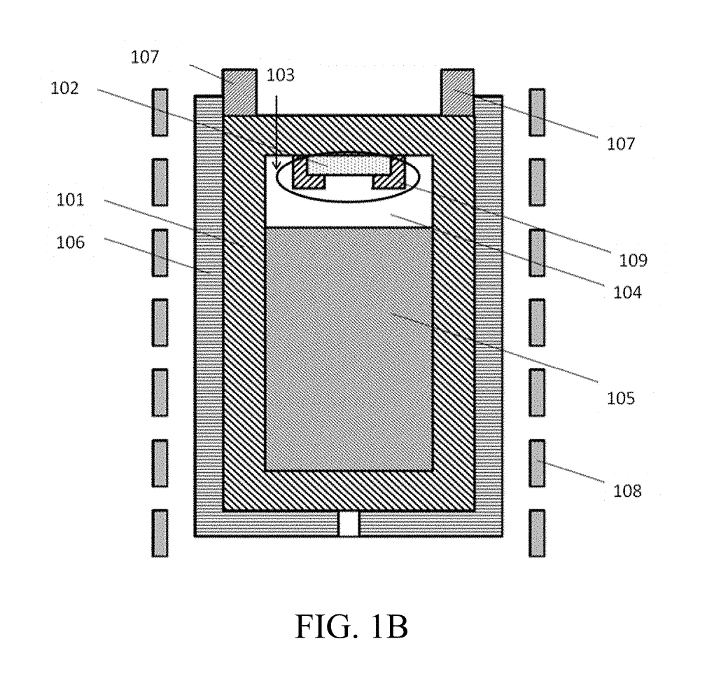

Referring to FIG. 1A, there is shown a schematic view of a device for growing monocrystalline crystals according to a preferred embodiment of the present invention. Referring to FIG. 1B, there is shown a schematic view of the device for growing monocrystalline crystals according to another embodiment of the present invention. As shown in FIG. 1A, the device for growing monocrystalline crystals comprises a crucible 101, a thermally insulating material 106, and a plurality of heating components 108. The crucible 101 has therein a seed crystal 102 for growing crystals from a material source. The crucible 101 comprises therein a seed crystal region 103, a growth chamber 104 and a material source region 105. The thermally insulating material 106 is disposed outside the crucible 101 and comprises a heat dissipation component 107 above. The heating components 108 are disposed outside the thermally insulating material 106 to provide heat sources. Each heating component 108 is a heating coil or a heating resistance wire/netting. The crucible 101 is a graphite crucible. The heat dissipation component 107 is made of a porous, thermally insulating carbon material, graphite, or a graphite felt. The thermally insulating material 106 is a graphite felt. In the preferred embodiment, the device further comprises a holder 109 disposed above the growth chamber 104 to secure the seed crystal 102 in the seed crystal region 103. The material source region 105 is disposed below the growth chamber 104 to contain a material source. In the preferred embodiment, the heating components 108, the crucible 101, the thermally insulating material 106, and the heat dissipation component 107 enable the device to control the temperature distribution, atmosphere flow, and powder sublimation in the crucible 101 and send the sublimed gas molecules to the seed crystal 102 (wafer) for deposition thereon. The heat dissipation component 107 increases the axial temperature difference, speeds up crystal growth, and controls interface shapes, thereby optimizing crystal growth. In the preferred embodiment, the device achieves the maximization of the heat dissipation space (central cavity) of the heat dissipation component 107 which is chimney-shaped or cylindrical (as shown in FIG. 1B) and thus the maximization of the axial temperature difference.

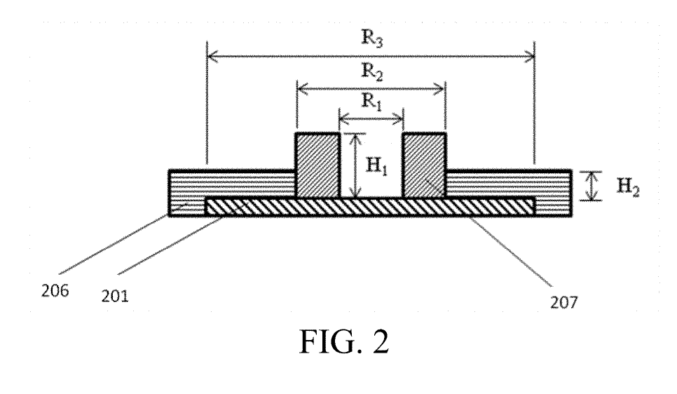

Referring to FIG. 2, there is shown a schematic view of a heat dissipation component of the device for growing monocrystalline crystals of the present invention. As shown in the diagram, 4-inch and 6-inch silicon carbide monocrystalline crystals are grown by PVT according to the present invention, characterized in that enhancement of monocrystalline crystal growth rate and control of interface shape are achieved with a heat dissipation component 207 which is chimney-shaped or cylindrical, but the present invention is not limited thereto. The heat dissipation component 207 is disposed on a graphite crucible 201. The heat dissipation component 207 is of a heat dissipation height H1, a heat dissipation inner diameter R1, and a heat dissipation outer diameter R2. The heat dissipation component 207 is enclosed by a thermally insulating material 206 of a width R3 and a height (thickness) H2. The temperature field inside the crucible is controlled by the heat dissipation inner diameter R1 and heat dissipation height H1 of the heat dissipation component 207 such that, during the crystal growth process, the seed crystal region at the bottom of the crucible has a temperature difference of 10-100° C., argon gas flow of 100-1000 sccm, and pressure of 1-200 torr, whereas the heat dissipation component 207 has the heat dissipation inner diameter R1 of 10˜250 mm (or the upper part of the thermally insulating material 206 has a width R3 of 1%˜85%), the heat dissipation outer diameter R2 of 15˜300 mm (or the upper part of the thermally insulating material 206 has a width R3 of 3%˜100%), and the heat dissipation height H1 of 5˜100 mm.

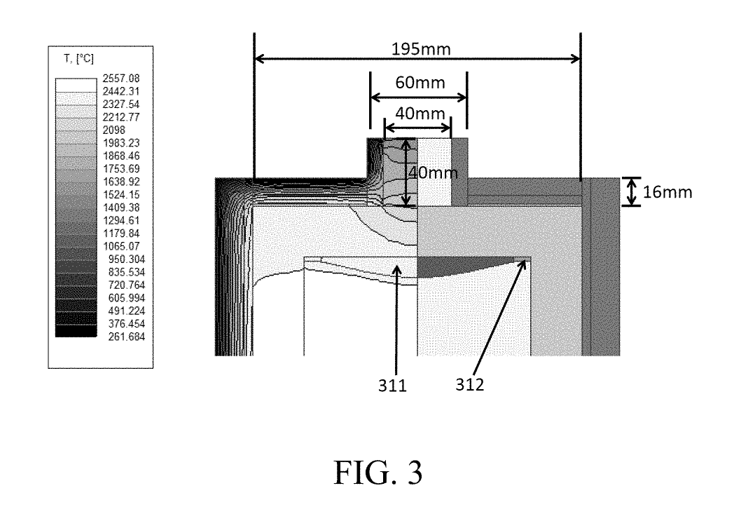

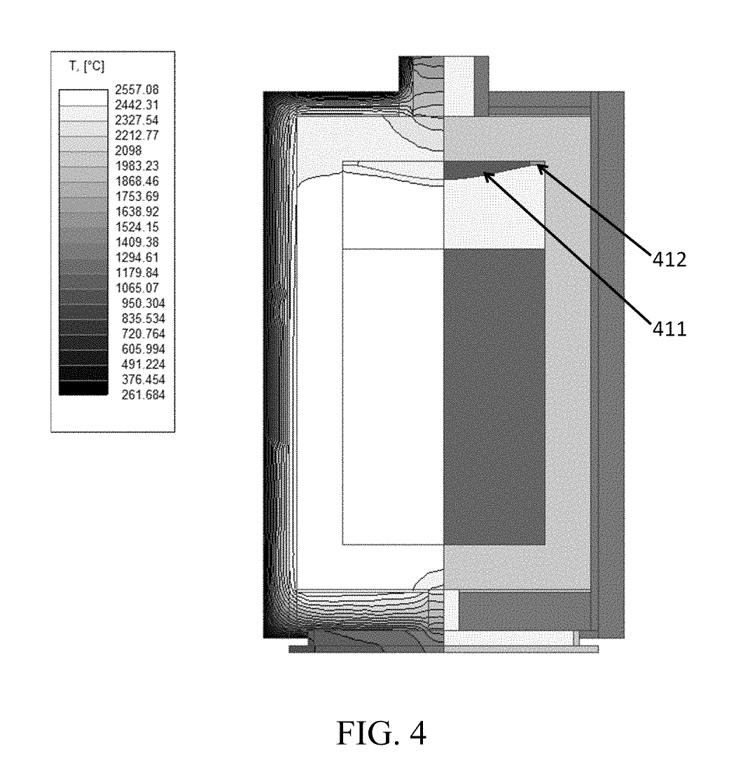

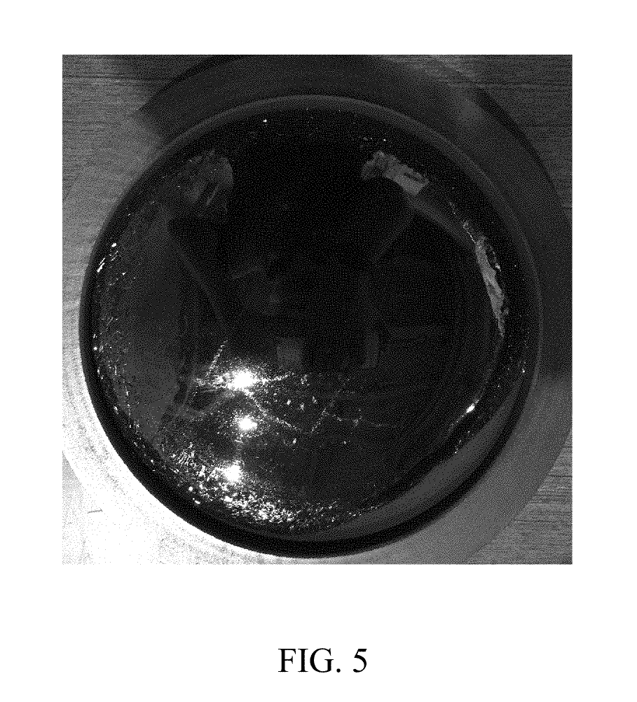

Referring to FIG. 3, there is shown a schematic view of thermal analysis of the heat dissipation component according to the preferred embodiment of the present invention. Referring to FIG. 4, there is shown a schematic view of thermal analysis of the device for growing monocrystalline crystals according to the preferred embodiment of the present invention. Referring to FIG. 5, there is shown a picture taken of a 6-inch monocrystalline silicon carbide crystal ball produced by the device for growing monocrystalline crystals according to the preferred embodiment of the present invention. As shown in FIG. 3, in the preferred embodiment, the heat dissipation component has a heat dissipation inner diameter R1 of 40 mm, a heat dissipation outer diameter R2 of 60 mm, and a heat dissipation height H1 of 40 mm, with the thermally insulating material 206 being of a height (thickness) H2 of 16 mm, and the thermally insulating material 206 having an upper part thereof being of a width R3 of 195 mm. In the preferred embodiment, the center of the seed crystal has an axial temperature gradient of around 71.84° C./cm and a radial temperature gradient of around −1.54° C./cm. In the preferred embodiment of the present invention, 4H—SiC monocrystalline crystals are grown at around 2100° C. and 5 torr for 30 hours in a high-temperature vacuum graphite crucible with the heat dissipation component by PVT from a raw material, that is, a high-purity silicon carbide powder of a purity of at least 99% and average particle diameter of 3-10 mm, using argon as a carrier gas. The seed crystal for use in the crystal growth process is a silicon carbide monocrystalline wafer of a thickness of at least 350 μm and a diameter of 2-6 inches. The 4H—SiC seed crystal is fixed in place by a holder and then undergoes ventilation to remove air and impurities from the crucible. During a heating step, an inert gas, such as argon or nitrogen, as well as an auxiliary gas, such as hydrogen, methane, and ammonia, are introduced into the crucible before the crucible is heated up with heating coils to around 2100° C. Referring to FIGS. 3, 4, polycrystalline regions 312, 412 account for a small part within the device for growing monocrystalline crystals, wherein the seed crystal region displays axial and radial temperature differences because of the heat dissipation component, and its convex temperature interface enables the centrally-located monocrystalline regions 311, 411 to grow outward, so as to further suppress the growth of the polycrystalline region and facilitate production of a 6 -inch monocrystalline silicon carbide crystal ball (shown in FIG. 5) with a convex wafer interface at a growth rate of 50-300 μm/hr. (The largest axial temperature difference occurs at the center, and thus monocrystalline crystals grow faster toward the center.)

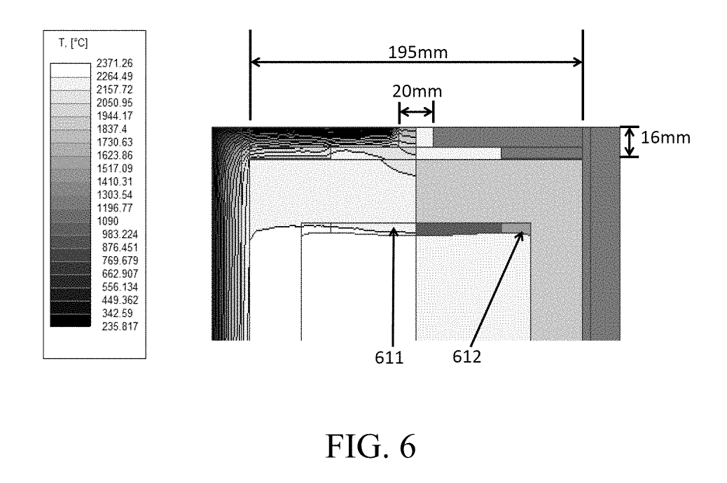

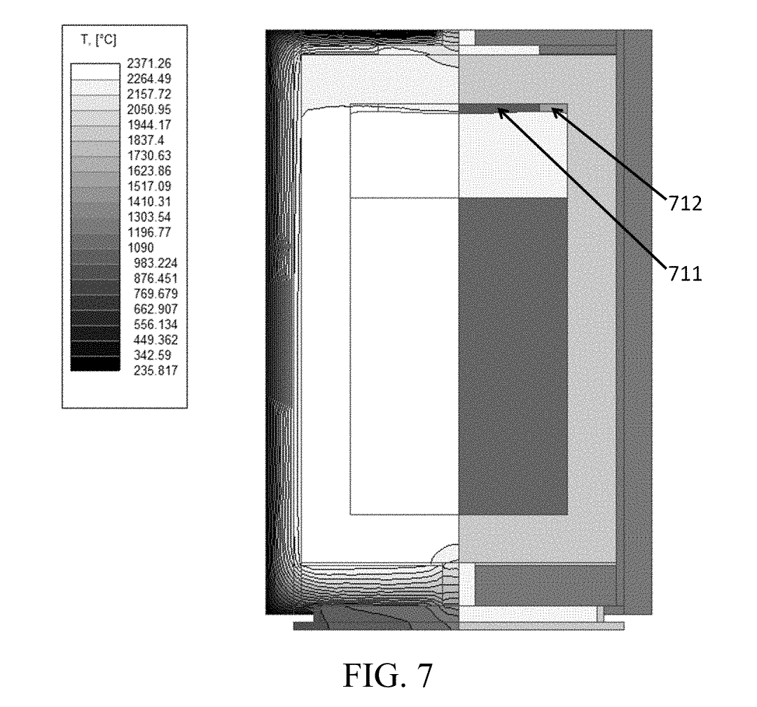

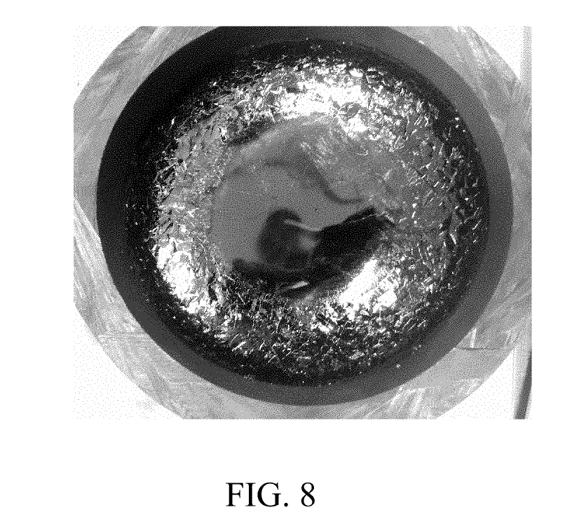

Referring to FIG. 6, there is shown a schematic view of thermal analysis of the heat dissipation component according to the comparative embodiment of the present invention. Referring to FIG. 7, there is shown a schematic view of thermal analysis of the device for growing monocrystalline crystals according to the comparative embodiment of the present invention. Referring to FIG. 8, there is shown a picture taken of a monocrystalline silicon carbide crystal ball produced by the device for growing monocrystalline crystals according to the comparative embodiment of the present invention. Referring to FIG. 6, the heat dissipation component has a heat dissipation hole of an inner diameter of 40 mm, whereas the thermally insulating material 206 has a height (thickness) H2 of 16 mm, wherein the upper part of the thermally insulating material 206 has a width of 195 mm In the comparative embodiment, the center of the seed crystal has an axial temperature gradient of around 35.34° C./cm and a radial temperature gradient of around 1.93° C./cm. The heat dissipation performance in the comparative embodiment and the preferred embodiment is illustrated with Table 1. Referring to FIGS. 6, 7, polycrystalline regions 612, 712 in the device of the comparative embodiment and polycrystalline regions 312, 412 in the device of the preferred embodiment are shown, respectively, indicating that the polycrystalline region 312, 412 account for a small part within the device according to the preferred embodiment, thereby providing a larger room for growing the monocrystalline crystals. Unlike the preferred embodiment, the comparative embodiment is characterized in that monocrystalline regions 611, 711 account for a small part within the device. Therefore, as shown in FIG. 8, in the comparative embodiment, only the center of the monocrystalline silicon carbide crystal ball produced by the device is monocrystalline, whereas the rest of the monocrystalline silicon carbide crystal ball produced by the device is polycrystalline; as a result, in the comparative embodiment, the device fails to produce any large monocrystalline silicon carbide crystal ball (of a diameter of 4-6 inches). Table 1: heat dissipation performance in the comparative embodiment and the preferred embodiment

| | axial | radial | maximum flux of |
|---|---|---|---|
| | temperature | temperature | radiation heat above |
| | gradient (° C./cm) | gradient (° C./cm) | crucible (10⁵ W/m²) |
| comparative | 35.34 | 1.93 | 3.17 |
| embodiment | | | |
| preferred | 71.84 | −1.54 | 5.90 |
| embodiment | | | |

According to the present invention, with the heat dissipation component being provided to control heat dissipation in the seed crystal region, the growth of the polycrystalline region is effectively suppressed while crystal growth is underway to produce large-sized monocrystalline crystals. Furthermore, growth efficiency increases toward the center of the seed crystal to thereby produce a 6 -inch monocrystalline crystal ball with a convex wafer interface. In addition, compared with the prior art, the present invention features an enhanced crystal growth rate and thus enables mass production of large-sized monocrystalline crystals.

The above embodiments are illustrative of the features and effects of the present invention rather than restrictive of the scope of the substantial technical disclosure of the present invention. Persons skilled in the art may modify and alter the above embodiments without departing from the spirit and scope of the present invention. Therefore, the scope of the protection of rights of the present invention should be defined by the appended claims.

What is claimed is:

1. A device for growing monocrystalline crystals, comprising:
a crucible adapted to grow crystals from a material source and with a seed crystal and including therein a seed crystal region, a growth chamber, and a material source region;
a thermally insulating material disposed outside the crucible and below a heat dissipation component; and
a plurality of heating components disposed outside the thermally insulating material to provide heat sources,
wherein the heat dissipation component is of a heat dissipation inner diameter and a heat dissipation height which exceeds a thickness of the thermally insulating material.

2. The device of claim 1, wherein the crucible is a graphite crucible.

3. The device of claim 1, wherein the heat dissipation inner diameter equals one of 10˜250 mm and 1%-85% of an outer diameter of an upper portion of the crucible.

4. The device of claim 1, wherein the heat dissipation height equals 5˜200 mm.

5. The device of claim 1, wherein the heat dissipation component is made of one of a porous, thermally insulating carbon material, a graphite, and a graphite felt.

6. The device of claim 1, wherein the thermally insulating material is a graphite felt.

7. The device of claim 1, wherein the material source region contains the material source.

8. The device of claim 1, wherein the material source is one of a silicon carbide powder and a nitride powder.

9. The device of claim 1, wherein the heating components are each one of a heating coil and a heating resistance wire/netting.

10. The device of claim 1, wherein the seed crystal is a monocrystalline wafer of a thickness of at least 350 μm and a diameter of 2-6 inches and is for growing monocrystalline crystals which outgrow the seed crystal in size.
